(19) United States
(12) Patent Application Publication
(10) Pub. No.: US 2026/0171372 A1
(43) Pub. Date: Jun. 18, 2026

(54) PLASMA PROCESSING APPARATUS

(71) Applicant: Tokyo Electron Limited, Tokyo (JP)

(72) Inventor: Kazuki HOSHI, Miyagi (JP)

(21) Appl. No.: 19/535,487

(22) Filed: Feb. 10, 2026

Related U.S. Application Data
(63) Continuation of application No. PCT/JP2024/028715, filed on Aug. 9, 2024.

(30) Foreign Application Priority Data
Aug. 22, 2023 (JP) 2023-134592

(51) Int. Cl. H01J 37/32

(52) U.S. Cl. CPC H01J 37/32715; H01J 2237/3321

(57) ABSTRACT

A plasma processing apparatus includes a processing chamber having a plasma processing space in which plasma is generated, the processing chamber being configured by a plurality of members; and a substrate support configured to support a substrate inside the processing chamber, the substrate support being configured by a plurality of members differing from the plurality of members included in the processing chamber. The processing chamber and/or the substrate support has a plurality of boundaries at which the plurality of members are connected to each other. The plurality of boundaries are provided with one or more radical blockers configured to block radicals generated in the plasma processing space; and one or more sealing portions configured to block passage of gas and provided at a position farther from the plasma processing space than the one or more radical blockers.

### CROSS-REFERENCE TO RELATED APPLICATIONS

This application is a continuation application of International Application No. PCT/JP2024/028715 filed on Aug. 9, 2024, and designating the U.S., which is based upon and claims priority to Japanese Patent Application No. 2023-134592 filed on Aug. 22, 2023, the entire contents of which are incorporated herein by reference.

### BACKGROUND

### 1. Technical Field

The present disclosure relates to a plasma processing apparatus.

### 2. Description of Related Art

Japanese Unexamined Patent Application Publication No. 2010-3958 (hereinafter “Patent Document 1”) discloses a plasma processing apparatus (plasma etching apparatus) including a processing vessel (processing chamber) for performing plasma processing and a substrate support (susceptor) provided inside the processing chamber for mounting a semiconductor wafer. This type of plasma processing apparatus includes various components, such as a lifter for elevating and lowering a substrate, wiring of an electrostatic chuck for electrostatically attracting the substrate, and wiring of a lower electrode for inducing radicals, inside the substrate support.

In order to protect the various components accommodated in the substrate support from radicals in the plasma processing space, the processing chamber and the substrate support are provided with high-performance sealing members exhibiting high durability against plasma and high temperatures at the boundaries between members.

### SUMMARY

According to one aspect of the present disclosure, there is provision of a plasma processing apparatus including a processing chamber having a plasma processing space in which plasma is generated, the processing chamber being configured by a plurality of members; and a substrate support configured to support a substrate inside the processing chamber, the substrate support being configured by a plurality of members differing from the plurality of members included in the processing chamber. The processing chamber and/or the substrate support has a plurality of boundaries at which the plurality of members are connected to each other. The plurality of boundaries are provided with one or more radical blockers configured to block radicals generated in the plasma processing space; and one or more sealing portions configured to block passage of gas and provided at a position farther from the plasma processing space than the one or more radical blockers.

### BRIEF DESCRIPTION OF THE DRAWINGS

FIG. 1 is a diagram schematically illustrating an overall configuration of a plasma processing system including a plasma processing apparatus according to an embodiment;

FIG. 2 is an enlarged cross-sectional view illustrating a lower side of a plasma processing chamber and a substrate support;

FIG. 3A is an enlarged cross-sectional view illustrating a sealing portion at point IIIA in FIG. 2;

FIG. 3B is an enlarged cross-sectional view illustrating a radical blocker at point IIIB in FIG. 2; and

FIG. 3C is an enlarged cross-sectional view illustrating a radical blocker according to a modified example.

### DETAILED DESCRIPTION

The present disclosure provides a technology capable of reducing environmental impact and cost by reducing the number of high-performance sealing members.

Hereinafter, an embodiment of the present disclosure will be described with reference to the accompanying drawings. In each of the drawings, the same components are denoted by the same reference numerals, and redundant descriptions may be omitted.

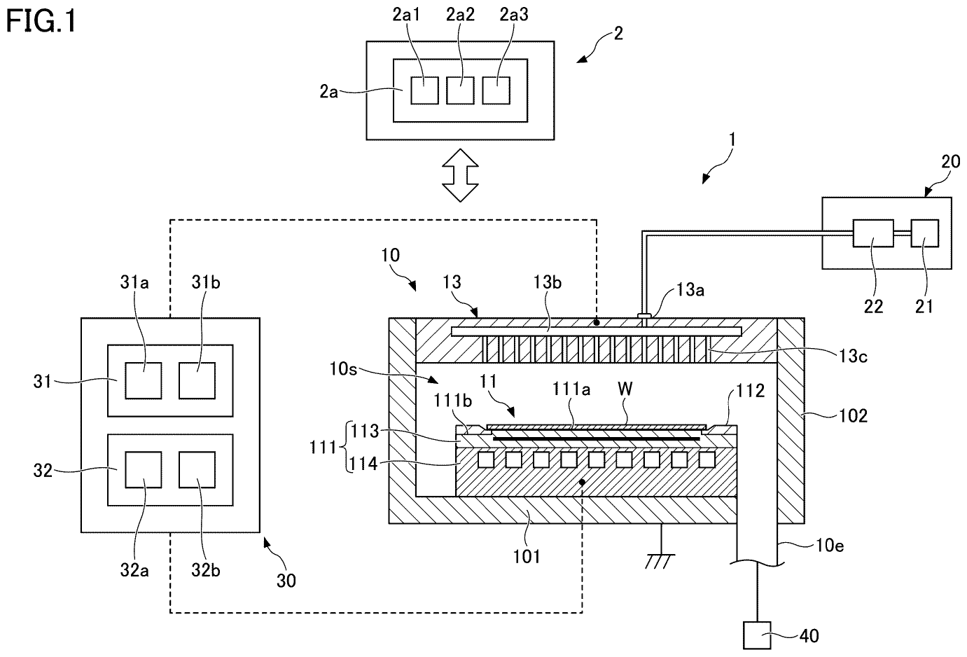

FIG. 1 is a diagram schematically illustrating an overall configuration of a plasma processing system having a plasma processing apparatus 1 according to an embodiment. First, a configuration example of a plasma processing system according to the embodiment will be described with reference to FIG. 1.

The plasma processing system includes a capacitively coupled plasma processing apparatus 1, which is a substrate processing apparatus, and a controller 2. The capacitively coupled plasma processing apparatus 1 includes a plasma processing chamber 10, a gas supply 20, a power source 30, and an exhaust system 40. The plasma processing apparatus 1 also includes a substrate support 11 and a gas introducing part. The gas introducing part is configured to introduce at least one type of process gas into the plasma processing chamber 10. The gas introducing part includes a showerhead 13. The substrate support 11 is disposed in the plasma processing chamber 10. The showerhead 13 is disposed above the substrate support 11. In the present embodiment, the showerhead 13 constitutes at least a part of the ceiling of the plasma processing chamber 10. The plasma processing chamber 10 has a plasma processing space 10s defined by the showerhead 13, the side walls 102 of the plasma processing chamber 10, and the substrate support 11. The plasma processing chamber 10 has at least one gas supply port for supplying at least one type of process gas to the plasma processing space 10s and at least one gas exhaust port for exhausting gases from the plasma processing space. The plasma processing chamber 10 is grounded. The showerhead 13 and the substrate support 11 are electrically isolated from the housing of the plasma processing chamber 10.

The substrate support 11 includes a main body 111 and a ring assembly 112. The main body 111 has a central region (substrate supporting surface) 111a for supporting a substrate (wafer) W and an annular region (ring supporting surface) 111b for supporting the ring assembly 112. The annular region 111b of the main body 111 encloses the central region 111a of the main body 111 in a plan view. A substrate W is placed on the central region 111a of the main body 111, and the ring assembly 112 is disposed on the annular region 111b of the main body 111 to enclose the substrate W on the central region 111a of the main body 111. In the present embodiment, the main body 111 includes an electrostatic chuck 113 and a base 114. The base 114 includes a conductive member. The conductive member of the base serves as a lower electrode. The electrostatic chuck 113 is disposed on the base 114. The upper surface of the electrostatic chuck 113 has the substrate supporting surface 111a. The ring assembly 112 includes one or more annular members. At least one of the one or more annular members is an edge ring.

The showerhead 13 is configured to introduce at least one type of process gas from the gas supply 20 into the plasma processing space 10s. The showerhead 13 has at least one gas supply port 13a, at least one gas diffusion chamber 13b, and a plurality of gas introduction ports 13c. The process gas supplied to the gas supply port 13a passes through the gas diffusion chamber 13b and is introduced into the plasma processing space 10s through the plurality of gas introduction ports 13c. The showerhead 13 also includes a conductive member. The conductive member of the showerhead 13 functions as an upper electrode. In addition to the showerhead 13, the gas introducing part may include one or more side gas injectors (SGIs) attached to one or more openings formed in the side wall 102.

The gas supply 20 may include at least one gas source 21 and at least one flow controller 22. In the present embodiment, the gas supply 20 is configured to supply at least one type of process gas to the showerhead 13 from a corresponding gas source 21 via a corresponding flow controller 22. Each flow controller 22 may include, for example, a mass flow controller or a pressure controlled flow controller. The gas supply 20 may further include one or more flow modulation devices that modulate or pulse the flow rate of at least one type of process gas.

The power source 30 includes an RF power source 31 coupled to the plasma processing chamber 10 via at least one impedance matching circuit. The RF power source 31 is configured to provide at least one RF signal (RF power), such as a source RF signal and a bias RF signal, to the conductive member of the substrate support 11 or the showerhead 13 or the conductive members of the substrate support 11 and the showerhead 13. This causes a plasma to be formed from at least one type of process gas supplied to the plasma processing space 10s. Thus, the RF power source 31 may function as at least part of a plasma generator configured to generate a plasma from one or more types of process gas in the plasma processing chamber 10. Upon supply of a bias RF signal to the conductive member of the substrate support 11, a bias potential may be generated in a substrate W to draw an ionic component in the formed plasma to the substrate W.

In the present embodiment, the RF power source 31 includes a first RF generator 31a and a second RF generator 31b. The first RF generator 31a is coupled to the conductive member of the substrate support 11 or the showerhead 13 or the conductive members of the substrate support 11 and the showerhead 13 via at least one impedance matching circuit. In the present embodiment, the source RF signal has a frequency in the range of 13 MHz to 150 MHz. In the present embodiment, the first RF generator 31a may be configured to generate a plurality of source RF signals having different frequencies. The generated one or more source RF signals are provided to the conductive member of the substrate support 11 or the showerhead 13 or the conductive members of the substrate support 11 and the showerhead 13. The second RF generator 31b is coupled to a conductive member of the substrate support 11 via at least one impedance matching circuit, and is configured to generate a bias RF signal (bias RF power). In the present embodiment, the bias RF signal has a lower frequency than the source RF signal. In the present embodiment, the bias RF signal has a frequency in the range of 400 kHz to 13.56 MHz. In the present embodiment, the second RF generator 31b may be configured to generate a plurality of bias RF signals having different frequencies. The generated bias RF signal or signals are provided to the conductive member of the substrate support 11. In various embodiments, at least one of the source RF signal and the bias RF signal may be pulsed.

The power source 30 may also include a DC power source 32 coupled to the plasma processing chamber 10. The DC power source 32 includes a first DC generator 32a and a second DC generator 32b. In the present embodiment, the first DC generator 32a is connected to the conductive member of the substrate support 11 and is configured to generate a first DC signal. The generated first bias DC signal is applied to the conductive member of the substrate support 11. In the present embodiment, the first DC signal may be applied to other electrodes, such as electrodes in an electrostatic chuck. In the present embodiment, the second DC generator 32b is connected to the conductive member of the showerhead 13 and is configured to generate a second DC signal. The generated second DC signal is applied to the conductive member of the showerhead 13. In various embodiments, at least one of the first DC signal or the second DC signal may be pulsed. The first and second DC generators 32a and 32b may be provided in addition to the RF power source 31, and the first DC generator 32a may be provided in place of the second RF generator 31b.

The exhaust system 40 may be connected, for example, to a gas exhaust port 10e provided at the bottom of the plasma processing chamber 10. The exhaust system 40 may include a pressure regulating valve and a vacuum pump. The pressure regulating valve regulates the pressure in the plasma processing space 10s. The vacuum pump may include a turbomolecular pump, a dry pump, or a combination thereof.

The controller 2 processes computer-executable instructions that cause the plasma processing apparatus 1 to perform various steps described herein. The controller 2 may be configured to control elements of the plasma processing apparatus 1 to perform various steps described herein. In the present embodiment, some or all of the controller 2 may be included in the plasma processing apparatus 1. The controller 2 may include, for example, a computer 2a. The computer 2a may include, for example, a processor (central processing unit, CPU) 2a1, a storage 2a2, and a communication interface 2a3. The processor 2al may be configured to perform various control operations based on a program stored in the storage 2a2. The storage 2a2 may include a RAM (random access memory), a ROM (read only memory), an HDD (hard disk drive), an SSD (solid state drive), or a combination thereof. The communication interface 2a3 may communicate with the plasma processing apparatus 1 via a communication line such as a LAN (local area network).

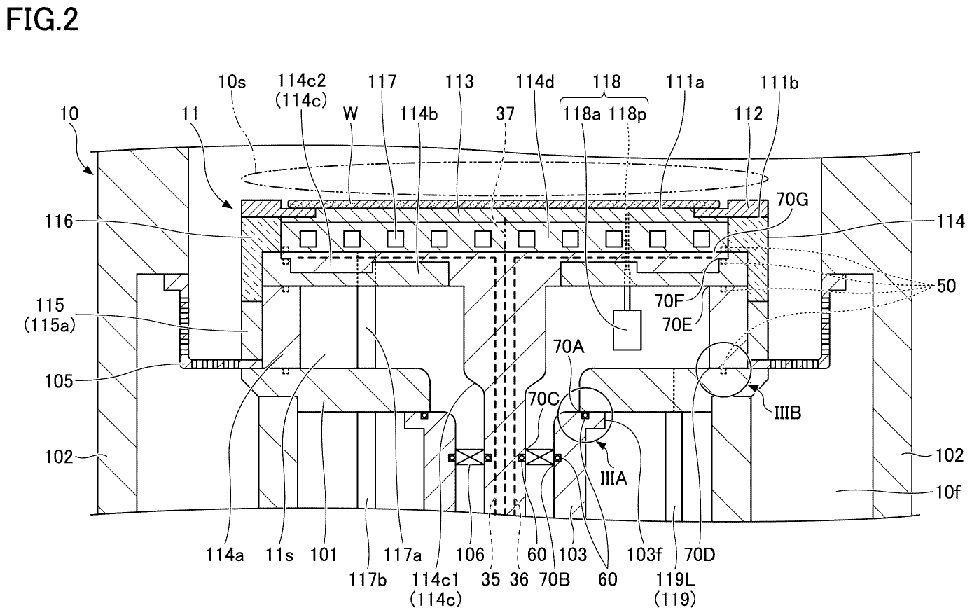

FIG. 2 is an enlarged cross-sectional view illustrating the lower side of the plasma processing chamber 10 and the substrate support 11. Next, the plasma processing chamber 10 and the substrate support 11 will be described more specifically with reference to FIG. 2.

The plasma processing chamber 10 has a bottom wall 101, a side wall 102 provided at an outer peripheral portion of the bottom wall 101, and a cylindrical wall (wall portion) 103 supporting the bottom wall 101 at a central portion of the bottom wall 101. The plasma processing chamber 10 is constructed by assembling a plurality of members constituting a wall. Although in FIG. 2 the bottom wall 101 and the side wall 102 are separated from each other because a passage 10f communicating with the gas exhaust port 10e is illustrated, they are continuous with each other (integrally formed) at a portion where the gas exhaust port 10e is not present.

The cylindrical wall 103 extends in the vertical direction and has a flange 103f in the upper side of the vertical direction. The flange 103f of the cylindrical wall 103 is connected to the bottom wall 101 by a fastening bolt (not illustrated). At a boundary 70A between the upper surface of the flange 103f and the lower surface of the bottom wall 101, a sealing portion 60 capable of airtightly closing the boundary 70A is provided. The configuration of the sealing portion 60 will be described later in detail.

The substrate support 11 (main body 111) has the electrostatic chuck 113 and the base 114 as described above. The base 114 is installed on the bottom wall 101 of the plasma processing chamber 10 and, together with the bottom wall 101 and the cylindrical wall 103, forms an interior space 11s for accommodating various components of the substrate support 11. The sealing portion 60 provided on the boundary 70A between the bottom wall 101 and the cylindrical wall 103 airtightly closes the boundary between the outside of the plasma processing chamber 10 and the interior space 11s of the substrate support 11.

The base 114 includes a cylindrical side portion 114a provided on the bottom wall 101, a ceiling portion 114b covering the upper end of the cylindrical side portion 114a, an accommodating portion 114c for accommodating various wirings of the substrate support 11, and a disk portion 114d provided between the accommodating portion 114c and the electrostatic chuck 113. In other words, the base 114 is configured by assembling a plurality of members. The base 114 has, on the outer peripheral surface of the cylindrical side portion 114a, a baffle plate holder 115 for holding the baffle plate 105 of the plasma processing chamber 10.

The baffle plate 105 is formed in an annular shape circumferentially around the side of the substrate support 11, and has a plurality of through-holes in the circumferential and radial directions penetrating in the thickness direction. The baffle plate 105 is connected to the ground potential via the plasma processing chamber 10. The baffle plate 105 thus configured forms a sheath electric field and allows a gas supplied to the plasma processing space 10s by the gas supply 20 to pass through the passage 10f, while blocking the passage of radicals in the plasma processing space 10s. As an example, the baffle plate holder 115 is constituted by a sandwiching member 115a having an annular shape in a plan view, which holds the inner end portion of the baffle plate 105 between the bottom wall 101 of the plasma processing chamber 10. The bottom wall 101 and the sandwiching member 115a may be a structure into which the baffle plate 105 is screwed.

The base 114 is provided with a protective member 116 above the baffle plate holder 115. The protective member 116 has a function of protecting the radial outer side of the ceiling portion 114b, the accommodating portion 114c, and the disk portion 114d. Similar to the sandwiching member 115a, the protective member 116 has an annular shape in a plan view and is formed of an insulating material such as quartz. The upper surface of the protective member 116 is flush with a step provided on the outer periphery of the electrostatic chuck 113, and forms the ring supporting surface 111b for supporting the ring assembly 112 together with the electrostatic chuck 113.

The cylindrical side portion 114a of the base 114 is installed on the bottom wall 101 of the plasma processing chamber 10, and protrudes from the upper surface of the bottom wall 101 toward the upper side of the vertical direction. The protruding height of the cylindrical side portion 114a is set higher than the height of the sandwiching member 115a. Therefore, the upper end of the cylindrical side portion 114a is positioned radially inward of the protective member 116 supported by the sandwiching member 115a.

The bottom wall 101 of the plasma processing chamber 10 and the cylindrical side portion 114a of the substrate support 11 (base 114) are fixed by fastening bolts or the like (not illustrated). A radical blocker 50 having a structure different from that of the sealing portion 60 is provided at a boundary 70D between the upper surface of the bottom wall 101 and the lower surface of the cylindrical side portion 114a. The structure of the radical blocker 50 will be described later in detail.

The ceiling portion 114b of the base 114 is formed in an annular shape that is wide in the radial direction, and its outer periphery is provided at the upper end of the cylindrical side portion 114a. An arrangement hole (not illustrated) for arranging the accommodating portion 114c is formed through the center of the ceiling portion 114b. The interior space 11s of the substrate support 11 is formed by the bottom wall 101, the cylindrical wall 103, the cylindrical side portion 114a, and the ceiling portion 114b of the plasma processing chamber 10.

The cylindrical side portion 114a and the ceiling portion 114b of the base 114 are fixed by fastening bolts or the like (not illustrated). A radical blocker 50 is provided at a boundary 70E between the upper surface of the cylindrical side portion 114a and the lower surface of the ceiling portion 114b.

The accommodating portion 114c of the base 114 is provided with a support column 114c1 extending along the vertical direction at the center of the substrate support 11, and a horizontal extending portion 114c2 extending radially outward on the vertical elevation side of the support column 114c1. In FIG. 2, the support column 114c1 and the horizontal extending portion 114c2 are illustrated by the same hatch and are integrated with each other, but the accommodating portion 114c may be composed of a plurality of members. The horizontal extending portion 114c2 is disposed between the ceiling portion 114b and the disk portion 114d and is supported by the ceiling portion 114b. In the accommodating portion 114c, the upper side of the support column 114c1 in the vertical direction and a part or all of the horizontal extending portion 114c2 is configured by a conductive member.

Although not illustrated, the inside of the support column 114c1 has one cavity or a plurality of passages. The support column 114c1 accommodates one or more wirings 35 connected to the RF power source 31, one or more wirings 36 connected to the DC power source 32, one or more wirings 37 connected to the electrostatic chuck 113, and the like. The wirings 35 and 36 extend radially outward from the upper portion of the support column 114c1 and are electrically connected to the conductive member of the horizontal extending portion 114c2. Thus, an appropriate signal from among a source RF signal, a bias RF signal, a first bias DC signal, a second bias DC signal, and the like is applied to the horizontal extending portion 114c2. The accommodating portion 114c may be formed of an insulating material, and the wirings 35 and 36 accommodated in the accommodating portion 114c may be connected to the disk portion 114d formed of a conductive material.

The ceiling portion 114b of the base 114 and the accommodating portion 114c (horizontal extending portion 114c2) are fixed by fastening bolts or the like (not illustrated). A radical blocker 50 is provided at a boundary 70F between the upper surface of the ceiling portion 114b and the lower surface of the accommodating portion 114c.

A partition member 106 for partitioning a space on the lower side of the cylindrical wall 103 from the interior space 11s is provided between the cylindrical wall 103 of the plasma processing chamber 10 and the support column 114c1 of the base 114. The partition member 106 is formed into an annular shape in a plan view and is made of a material capable of blocking the movement of gas. The sealing portion 60 is provided at a boundary 70B between the outer peripheral surface of the partition member 106 and the inner peripheral surface of the cylindrical wall 103. Similarly, the sealing portion 60 is provided at a boundary 70C between the inner peripheral surface of the partition member 106 and the outer peripheral surface of the support column 114c1. Thus, the plasma processing apparatus 1 can airtightly close the lower portion of the interior space 11s of the substrate support 11. The plasma processing apparatus 1 may have a configuration in which the substrate support 11 is rotatable relative to the plasma processing chamber 10, such as a configuration in which the support column 114c1 is rotated axially so that the member on the upper side in the vertical direction is rotated. In this case, instead of the partition member 106, the plasma processing apparatus 1 may apply a magnetic fluid seal for sealing the interior space 11s while making the support column 114c1 rotatable.

The disk portion 114d of the base 114 is provided on the upper surface of the accommodating portion 114c (the horizontal extending portion 114c2) and supports the electrostatic chuck 113. The upper surface of the disk portion 114d and the lower surface of the electrostatic chuck 113 are firmly fixed to each other by using an adhesive or the like having a high thermal conductivity. The disk portion 114d has therein a temperature adjustor 117 for adjusting at least one of the substrate W or the ring assembly 112 to a target temperature. The temperature adjustor 117 is configured by elements including a heater for heating based on power source, a flow path for circulating a heat transfer fluid such as brine or gas, or a combination thereof (FIG. 2 illustrates a flow path). Alternatively, the substrate support 11 may include a heat transfer gas supply for supplying heat transfer gas between the rear surface of the substrate W and the substrate supporting surface 111a.

The accommodating portion 114c (horizontal extending portion 114c2) of the base 114 and the disk portion 114d are fixed by a fastening bolt or the like, which is not illustrated. The radical blocker 50 is provided at a boundary 70G between the upper surface of the accommodating portion 114c and the lower surface of the disk portion 114d. As described above, the base 114 is provided with a plurality of radical blockers 50 (four in the present embodiment) positioned along the height of the outer peripheral portion (along the vertical direction), the radical blockers 50 being aligned at substantially the same planar position in a plan view. Thus, the radical blockers 50 having the same structure are applicable to the plasma processing apparatus 1, and a common member can be used.

The electrostatic chuck 113 provided on the upper surface of the disk portion 114d of the base 114 is electrically connected to the wiring 37 passing through the inside of the base 114 (the accommodating portion 114c and the disk portion 114d). The electrostatic chuck 113 generates an electrostatic force based on electric power supplied from the wiring 37 and electrostatically attracts the substrate W placed on the substrate supporting surface 111a. Although FIG. 2 illustrates the electrostatic chuck 113 for electrostatically attracting the substrate W, the substrate support 11 may hold the substrate W by vacuum sucking or mechanical locking.

As described above, a step lower than the substrate supporting surface 111a is formed on the outer periphery of the electrostatic chuck 113. The electrostatic chuck 113 also supplies power to the step to electrostatically attract the ring assembly 112. The electrostatic chuck 113 transmits the temperature adjusted by the temperature adjustor 117 of the disk portion 114d to the substrate W, and draws radicals generated in the plasma processing space 10s to the electrostatic chuck 113 (substrate W) side based on an appropriate signal from the power source 30.

Furthermore, the substrate support 11 is provided with a plurality of pipes 117a of the temperature adjustor 117, a plurality of lifters 118, and the like to be accommodated in the interior space 11s provided inside the base 114 (in FIG. 2, one pipe 117a and one lifter 118 are representatively illustrated). Alternatively, the substrate support 11 may be provided with the wiring 37, which is provided in the accommodating portion 114c, in the interior space 11s, or may be provided with a fluorescent thermometer or the like, which is not illustrated, in the interior space 11s.

The pipes 117a of the temperature adjustor 117 communicate with the pipes 117b provided outside the plasma processing chamber 10 via the bottom wall 101. Each pipe 117b is connected to a chiller (not illustrated) or the like for adjusting the temperature of a heat transfer fluid. Each pipe 117a has an interior space 11s extending in the vertical direction and communicating with the flow path of the disk portion 114d. Thus, the temperature adjustor 117 circulates the heat transfer fluid through the pipes 117a and 117b and the flow path of the disk portion 114d.

Each lifter 118 has a pin 118p extending in the vertical direction and a drive portion 118a for raising and lowering the pin 118p. Each lifter 118 raises and lowers the pin 118p from the substrate supporting surface 111a to receive and deliver a substrate W to and from a transport device (not illustrated).

The plasma processing chamber 10 may be provided with a decompressor 119 for decompressing the interior space 11s of the substrate support 11. The decompressor 119 includes, for example, a decompression pipe 119L connected to the bottom wall 101, and the decompression pipe 119L is connected to a pressure regulating valve and a vacuum pump (not illustrated) provided separately from the exhaust system 40. The plasma processing chamber 10 can smoothly decompress the interior space 11s of the substrate support 11 by providing the decompressor 119 separately from the exhaust system 40 for decompressing the plasma processing space 10s. The decompressor 119 may be connected to a vacuum pump of the exhaust system 40.

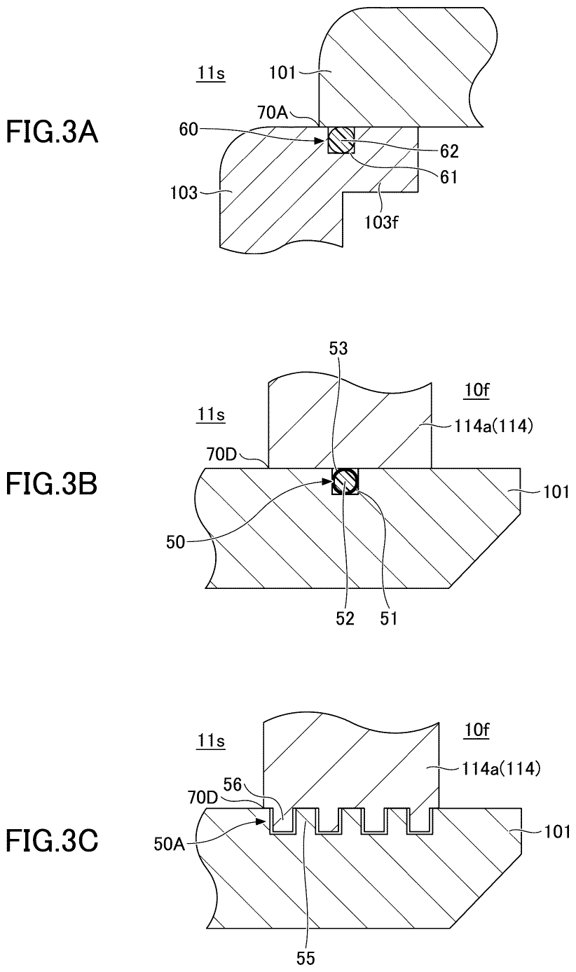

Next, the configurations of the sealing portions 60 and the radical blockers 50 provided in the plasma processing apparatus 1 will be described with reference to FIGS. 3A through 3C. FIG. 3A is an enlarged cross-sectional view illustrating the sealing portion 60 at point IIIA in FIG. 2. FIG. 3B is an enlarged cross-sectional view illustrating the radical blocker 50 at point IIIB in FIG. 2. FIG. 3C is an enlarged cross-sectional view illustrating the radical blocker 50A according to a modified example. Hereinafter, the sealing portion 60 provided at the boundary 70A between the bottom wall 101 and the cylindrical wall 103 in FIG. 3A will be described as a representative example; however, the sealing portions 60 provided at other locations have a similar configuration. The radical blocker 50 provided at the boundary 70D between the bottom wall 101 and the cylindrical side portion 114a in FIG. 3B will be described as a representative example; however, the radical blockers 50 provided at other locations have a similar configuration.

The sealing portion 60 includes a groove 61 and a sealing member 62 accommodated in the groove 61. Although the sealing portion 60 is formed in the flange 103f of the cylindrical wall 103 in FIG. 3A, the sealing portion 60 may be provided in the bottom wall 101. In short, for each of the boundaries 70A through 70C, the sealing portion 60 may be provided in one (or both) of the two members forming the boundary.

The groove 61 of the sealing portion 60 is formed at a position opposite to the bottom wall 101, and circulates annularly around the upper surface of the cylindrical wall 103 (flange 103f) in a plan view. The depth of the groove 61 is set smaller than the diameter of the sealing member 62.

The sealing member 62 is formed into an O-ring accommodated in the annular groove 61. The sealing member 62 is elastically deformed when a portion of the sealing member 62 protruding from the groove 61 contacts the bottom wall 101 while the sealing member 62 is accommodated in the groove 61. Thus, the sealing member 62 can airtightly close the outside of the plasma processing chamber 10 and the interior space 11s. Although FIG. 3A illustrates the solid sealing member 62 in a cross-sectional view, the sealing member 62 may be hollow in a cross-sectional view.

As illustrated in FIG. 2, the sealing portions 60 provided in the plasma processing apparatus 1 are not in the vicinity of the plasma processing space 10s. In other words, the sealing portions 60 are positioned radially inward of the outer circumferential portion (the cylindrical side portion 114a, etc.) of the substrate support 11, and are provided on the opposite side of the ceiling portion 114b of the base 114 across the interior space 11s. In other words, the sealing portions 60 airtightly close the lower side of the interior space 11s in the vertical direction at a position where radicals generated in the plasma processing space 10s cannot reach and heat of the plasma processing space 10s is not readily transmitted.

Therefore, a general-purpose O-ring having low plasma durability and low heat resistance can be applied to the sealing members 62 accommodated in the sealing portions 60. Specifically, a sealing member 62 made of an organic compound containing no fluorine or silicone can be selected. Examples of the material of the sealing member 62 of this kind include nitrile rubber, acrylic rubber, ethylene propylene rubber, chloroprene rubber, and the like. Alternatively, natural rubber or natural synthetic rubber may be applied to the sealing member 62.

As illustrated in FIG. 3B, the radical blocker 50 also includes a groove 51 and a sealing member 52 accommodated in the groove 51. Although the radical blocker 50 is formed in the bottom wall 101 in FIG. 3B, the radical blocker 50 may be provided in the cylindrical side portion 114a. In short, for each of the boundaries 70D through 70G, the radical blocker 50 may be provided in one or both of the two members that form the respective boundary.

The groove 51 of the radical blocker 50 is formed at a position opposed to the cylindrical side portion 114a, and circulates annularly around the upper surface of the bottom wall 101 in a plan view. The depth of the groove 51 is set smaller than the diameter of the sealing member 52.

The sealing member 52 is formed into an O-ring accommodated in the annular groove 51. While the sealing member 52 is accommodated in the groove 51, the sealing member 52 elastically deforms when a portion of the sealing member 52 protruding from the groove 51 contacts the cylindrical side portion 114a. Thus, the sealing member 52 can airtightly close the outside (passage 10f) of the substrate support 11 and the interior space 11s. Although FIG. 3B illustrates the solid sealing member 52 in a cross-sectional view, the sealing member 52 may be hollow in a cross-sectional view.

Herein, as illustrated in FIG. 2, each of the radical blockers 50 provided in the plasma processing apparatus 1 is located closer to the plasma processing space 10s than the sealing portions 60. In other words, each of the radical blockers 50 is located at an outer peripheral portion of the substrate support 11, where radicals generated in the plasma processing space 10s may reach, and where heat of the plasma processing space 10s is easily transmitted.

Therefore, a high-performance O-ring having high plasma durability and high heat resistance is applied to the sealing member 52 contained in each of the radical blockers 50. Specifically, the sealing member 52 may be made of an organic compound containing one or both of fluorine, silicone, and the like. Examples of the material of this type of sealing member 52 include fluoro rubber (FKM, FPM), tetrafluoroethylene-propylene fluoro rubber (FPEM), and perfluoro elastomer (FFKM). The surface of the sealing member 52 may be coated with a coating 53 having plasma resistance and heat resistance.

However, since the substrate support 11 is installed inside the plasma processing chamber 10 in a vacuum atmosphere, the interior space 11s can be evacuated (decompressed) even if the interior space 11s is in communication with the plasma processing space 10s. Therefore, the radical blockers 50 need not have a function of completely blocking the interior space 11s. For example, instead of the sealing member 52, the radical blockers 50 may be filled with a material (plasma-resistant and heat-resistant hardeners, porous materials, etc.) that fills a gap between the two members (including the groove 51) forming the respective boundary.

As illustrated in FIG. 3C, since the bottom wall 101 has an uneven portion 55 and the cylindrical side portion 114a has an uneven portion 56, the radical blocker 50A according to the modified example forms a labyrinth structure in which the uneven portions 55 and 56 are fitted together. Even when the labyrinth structure is applied, the radical blocker 50A can block radicals in the plasma processing space 10s from flowing toward the interior space 11s. The radical blocker 50A may be filled with a material (plasma-resistant and heat-resistant hardeners, porous materials, etc.) that fills a gap between the uneven portions 55 and 56.

The plasma processing apparatus 1 according to the embodiment is basically configured as described above. In the plasma processing apparatus 1, a substrate W is placed on the substrate supporting surface 111a of the substrate support 11, and the substrate W is electrostatically attracted. Thereafter, the plasma processing apparatus 1 generates a plasma in the plasma processing space 10s by supplying RF power from the power source 30 to the substrate support 11 and the showerhead 13 while supplying the process gas from the gas supply 20. Thus, the plasma processing apparatus 1 can perform an appropriate plasma processing (etching, film formation, etc.) on the substrate W.

The plasma processing apparatus 1 has the radical blockers 50 and the sealing portions 60 in the plasma processing chamber 10 and the substrate support 11. For example, the substrate support 11 can decompress the interior space 11s by the decompressor 119 to form a vacuum atmosphere. In the plasma processing apparatus 1, even if a plasma is generated in the plasma processing space 10s, the radical blockers 50 can prevent the entry of radicals into the interior space 11s to maintain an environment in the substrate support 11 in an appropriate state. Thus, deterioration of various components in the substrate support 11 can be greatly suppressed. Furthermore, in the plasma processing apparatus 1, even if the configuration can prevent the entry of radicals, a general-purpose sealing member 62 can be used at a location away from the plasma processing space 10s. This allows the number of high-performance sealing members 52 to be reduced, thereby reducing environmental impact and cost.

In particular, by providing the radical blockers 50 at the outer periphery of the substrate support 11, it is possible to prevent the entry of radicals into the outer peripheral region. Moreover, since the sealing portions 60 are positioned radially inward of the radical blockers 50, exposure to radicals can be more reliably suppressed. The plurality of lifters 118 accommodated in the interior space 11s of the substrate support 11 are also prevented from being degraded by radicals. Furthermore, since the plasma processing apparatus 1 is provided with the decompressor 119, the interior space 11s can be turned into a vacuum atmosphere in a short time, and it is possible to efficiently adjust the pressure of the entire plasma processing chamber 10.

It should be noted that the positions of the radical blockers 50 and the sealing portions 60 are not limited to the above-described embodiment, and may be freely designed. For example, in the above-described embodiment, the radical blocker 50 is provided at the boundary 70D between the bottom wall 101 and the substrate support 11 (the cylindrical side portion 114a), thereby enhancing the blocking performance of radicals. However, the sealing portion 60, instead of the radical blocker 50, may be provided at the boundary 70D between the bottom wall 101 and the cylindrical side portion 114a. This is because this position is away from the plasma processing space 10s to some extent and is hardly affected by plasma. The radical blocker 50 may be provided at the boundary between the sandwiching member 115a and the protective member 116, or may be provided at the boundary between the electrostatic chuck 113 and the base 114 (the disk portion 114d).

The embodiment disclosed above includes, for example, the following aspects.

### <Clause 1>

A plasma processing apparatus, including:
a processing chamber having a plasma processing space in which plasma is generated, the processing chamber being configured by a plurality of members; and
a substrate support configured to support a substrate inside the processing chamber, the substrate support being configured by a plurality of members differing from the plurality of members included in the processing chamber, wherein
the processing chamber and the substrate support, the processing chamber, or the substrate support has a plurality of boundaries at which the plurality of members are connected to each other, and
the plurality of boundaries are provided with
   one or more radical blockers configured to block radicals generated in the plasma processing space; and
   one or more sealing portions configured to block passage of gas and provided at a position farther from the plasma processing space than the one or more radical blockers.

### <Clause 2>

The plasma processing apparatus according to Clause 1, wherein
the one or more radical blockers are provided in an outer peripheral portion of the substrate support.

### <Clause 3>

The plasma processing apparatus according to Clause 2, wherein
the substrate support includes an interior space radially inward of the outer peripheral portion, and
a plurality of lifters configured to elevate and lower the substrate supported by the substrate support are accommodated in the interior space.

### <Clause 4>

The plasma processing apparatus according to Clause 3, further including
a decompressor configured to reduce a pressure of the interior space, the decompressor being provided separately from an exhaust system configured to reduce a pressure by drawing gas from the plasma processing space.

### <Clause 5>

The plasma processing apparatus according to any one of Clauses 2 to 4, wherein
the one or more sealing portions are positioned radially inward of the one or more radical blockers provided in the substrate support.

### <Clause 6>

The plasma processing apparatus according to any one of Clauses 2 to 5, wherein
the one or more radical blockers provided in the substrate support are provided along a height of the outer peripheral portion of the substrate support, the one or more radical blockers being aligned at substantially the same planar position in a plan view.

### <Clause 7>

The plasma processing apparatus according to any one of Clauses 1 to 6, wherein
the processing chamber includes a bottom wall to which the substrate support is fixed, and
a boundary between the bottom wall and the substrate support is provided with one of the one or more radical blockers, the boundary being one of the plurality of boundaries.

### <Clause 8>

The plasma processing apparatus of Clause 7, wherein
the processing chamber includes a wall portion coupled to the bottom wall, and
a boundary between the bottom wall and the wall portion is provided with one of the one or more sealing portions, the boundary being another of the plurality of boundaries.

### <Clause 9>

The plasma processing apparatus of Clause 8, wherein
the substrate support includes a support column configured to accommodate a wiring capable of supplying power, the support column being located inside the wall portion, and a partition member configured to partition a space between the support column and the wall portion, and
a boundary between the support column and the partition member is provided with another of the one or more sealing portions, the boundary being another of the plurality of boundaries.

### <Clause 10>

The plasma processing apparatus according to any of Clauses 1 to 9, wherein
at least one radical blocker of the one or more radical blockers includes a groove and a sealing member formed of a material containing fluorine and accommodated in the groove.

### <Clause 11>

The plasma processing apparatus according to any one of Clauses 1 to 10, wherein
at least one radical blocker of the one or more radical blockers has a labyrinth structure formed by uneven portions formed in the plurality of members included in the processing chamber and the substrate support.

### <Clause 12>

The plasma processing apparatus according to any one of Clauses 1 to 11, wherein
the one or more sealing portions include a groove and a sealing member formed of a fluorine-free material and accommodated in the groove.

The plasma processing apparatus 1 according to the embodiment disclosed herein is exemplary in all respects and is not intended to be limiting. The embodiment may be modified and improved in various forms without departing from the scope and gist of the appended claims. The matters described in the above embodiments can be incorporated into other configurations and combined without conflict.

The plasma processing apparatus 1 of the present disclosure is applicable to any type of apparatus including an atomic layer deposition (ALD) apparatus and capacitively coupled plasma (CCP), inductively coupled plasma (ICP), radial line slot antenna (RLSA), electron cyclotron resonance (ECR) plasma, and helicon wave plasma (HWP) apparatuses.

What is claimed is:

1. A plasma processing apparatus, comprising:
a processing chamber having a plasma processing space in which plasma is generated, the processing chamber being configured by a plurality of members; and
a substrate support configured to support a substrate inside the processing chamber, the substrate support being configured by a plurality of members differing from the plurality of members included in the processing chamber, wherein
the processing chamber and the substrate support, the processing chamber, or the substrate support has a plurality of boundaries at which the plurality of members are connected to each other, and
the plurality of boundaries are provided with
one or more radical blockers configured to block radicals generated in the plasma processing space; and
one or more sealing portions configured to block passage of gas and provided at a position farther from the plasma processing space than the one or more radical blockers.

2. The plasma processing apparatus according to claim 1, wherein
the one or more radical blockers are provided in an outer peripheral portion of the substrate support.

3. The plasma processing apparatus according to claim 2, wherein
the substrate support includes an interior space radially inward of the outer peripheral portion, and
a plurality of lifters configured to elevate and lower the substrate supported by the substrate support are accommodated in the interior space.

4. The plasma processing apparatus according to claim 3, further comprising
a decompressor configured to reduce a pressure of the interior space, the decompressor being provided separately from an exhaust system configured to reduce a pressure by drawing gas from the plasma processing space.

5. The plasma processing apparatus according to claim 2, wherein
the one or more sealing portions are positioned radially inward of the one or more radical blockers provided in the substrate support.

6. The plasma processing apparatus according to claim 2, wherein
the one or more radical blockers provided in the substrate support are provided along a height of the outer peripheral portion of the substrate support, the one or more radical blockers being aligned at substantially the same planar position in a plan view.

7. The plasma processing apparatus according to claim 1, wherein
the processing chamber includes a bottom wall to which the substrate support is fixed, and
a boundary between the bottom wall and the substrate support is provided with one of the one or more radical blockers, the boundary being one of the plurality of boundaries.

8. The plasma processing apparatus of claim 7, wherein
the processing chamber includes a wall portion coupled to the bottom wall, and
a boundary between the bottom wall and the wall portion is provided with one of the one or more sealing portions, the boundary being another of the plurality of boundaries.

9. The plasma processing apparatus of claim 8, wherein
the substrate support includes a support column configured to accommodate a wiring capable of supplying power, the support column being located inside the wall portion, and a partition member configured to partition a space between the support column and the wall portion, and
a boundary between the support column and the partition member is provided with another of the one or more sealing portions, the boundary being another of the plurality of boundaries.

10. The plasma processing apparatus according to claim 1, wherein
at least one radical blocker of the one or more radical blockers includes a groove and a sealing member formed of a material containing fluorine and accommodated in the groove.

11. The plasma processing apparatus according to claim 1, wherein
at least one radical blocker of the one or more radical blockers has a labyrinth structure formed by uneven portions formed in the plurality of members included in the processing chamber and the substrate support.

12. The plasma processing apparatus according to claim 1, wherein
the one or more sealing portions include a groove and a sealing member formed of a fluorine-free material and accommodated in the groove.
